(19) United States
(12) Patent Application Publication
(10) Pub. No.: US 2024/0379925 A1
(43) Pub. Date: Nov. 14, 2024

(54) TRANSPARENT DISPLAY APPARATUS AND MANUFACTURING METHOD THEREOF

(71) Applicant: Global Technologies Co., LTD, Hwaseong-si Gyeonggi-do (KR)

(72) Inventors: Min Seon KIM, Hwaseong-si Gyeonggi-do (KR); Yong Geun KIM, Suwon-si Gyeonggi-do (KR)

(73) Assignee: Global Technologies Co., LTD, Hwaseong-si Gyeonggi-do (KR)

(21) Appl. No.: 18/659,816

(22) Filed: May 9, 2024

(30) Foreign Application Priority Data
May 10, 2023 (KR) 10-2023-0060591

(51) Int. Cl. H01L 33/62; H01L 25/075

(52) U.S. Cl. CPC H01L 33/62; H01L 25/0753; H01L 2933/0066

(57) ABSTRACT

The present disclosure relates to a transparent display apparatus and manufacturing method thereof configured to prevent sharp bending of wiring to increase transparency (aesthetics) and prevent noises according to wiring shapes such as a reflected waveform; and may include a first power wire formed on the light transmitting substrate, which supplies power; and a light emitting part which receives power from the first power wire to emit light; wherein the first power wire may include a first wave pattern part formed by repeatedly connecting a curve-shaped first peak part and a curve-shaped first valley part in an overall wave shape in a length direction to prevent sharp bending.

### CROSS-REFERENCE TO RELATED APPLICATION(S)

This application is based on and claims priority under 35 U.S.C. § 119 (a) to Korean Patent Application No. 10-2023-0060591, filed on May 10, 2023, in the Korean Intellectual Property Office, the entire contents of which application is incorporated herein by reference.

### TECHNICAL FIELD

The present disclosure relates to a transparent display apparatus and manufacturing method thereof, and more specifically to a transparent display apparatus and manufacturing method thereof configured to prevent sharp bending of wiring to increase transparency (aesthetics) and prevent noises according to wiring shapes such as a reflected waveform.

### BACKGROUND

In general, a transparent display apparatus in which a plurality of light emitting devices such as LEDs, mini-LEDs, micro-LEDs and the like are mounted on a light transmitting substrate, may include a wiring layer composed of a conductive material such as metal to apply power or control signals to the light emitting devices.

Such wiring layers are formed with small line widths to increase transparency (aesthetics) and accordingly, the wires were easily disconnected.

Conventionally, in order to compensate for such disconnections, a polygonal wiring layer that forms a mesh in a polygonal pattern such as a rectangular or a hexagonal pattern was used. However, such a polygonal pattern also frequently caused pattern breaks in the direction of travel, especially in the rectangular or the hexagonal pattern. There were also problems such as generation of noise or electromagnetic waves such as reflected waveforms in transmission line theory and electromagnetism because sharp bends were inevitably formed at angled parts such as the rectangular or the hexagonal pattern.

### SUMMARY

According to an aspect of the present disclosure, a transparent display apparatus may include a light transmitting substrate; a first power wire formed on the light transmitting substrate, which supplies power; and a light emitting part which receives power from the first power wire to emit light; wherein the first power wire may include a first wave pattern part formed by repeatedly connecting a curve-shaped first peak part and a curve-shaped first valley part in an overall wave shape in a length direction to prevent sharp bending.

Meanwhile, according to an aspect of the present disclosure, a manufacturing method of the transparent display apparatus may include a step (a) wherein a light transmitting substrate is prepared; a step (b) wherein a first power wire is formed on the light transmitting substrate; and a step (c) wherein a light emitting part is formed on the first power wire, which receives power form the first power wire to emit light; wherein in the step (b), a first wave pattern part may be formed by repeatedly connecting a curve-shaped first peak part and a curve-shaped first valley part in an overall wave shape in the length direction to prevent sharp bending.

### BRIEF DESCRIPTION OF DRAWINGS

FIG. 1 is a top plan view showing a transparent display apparatus according to some embodiments of the present disclosure.

FIG. 2 is an enlarged top plan view showing the transparent display apparatus of FIG. 1.

FIG. 3 is a cross-sectional side view of the transparent display apparatus of FIG. 1.

FIGS. 4 to 10 are cross-sectional side views showing examples of manufacturing processes of the transparent display apparatus of FIG. 1 step by step.

FIGS. 11 to 16 are cross-sectional side views showing other examples of the manufacturing processes of the transparent display apparatus of FIG. 1 step by step.

FIG. 17 is a top plan view showing a transparent display apparatus according to some other embodiments of the present disclosure.

FIG. 18 is a top plan view showing a transparent display apparatus according to some further embodiments of the present disclosure.

FIG. 19 is a top plan view showing a transparent display apparatus according to some further embodiments of the present disclosure.

FIG. 20 is a top plan view showing a transparent display apparatus according to some further embodiments of the present disclosure.

FIG. 21 is a flowchart showing a manufacturing method of a transparent display apparatus according to some embodiments of the present disclosure.

FIG. 22 is a flowchart showing an example of step (b) of the manufacturing method of the transparent display apparatus of FIG. 21.

FIG. 23 is a flowchart showing another example of step (b) of the manufacturing method of the transparent display apparatus of FIG. 21.

### DETAILED DESCRIPTION OF EXEMPLARY EMBODIMENTS

Hereinafter, the present disclosure will be described in detail by explaining embodiments of the present disclosure with reference to the attached drawings.

Various embodiments of the present disclosure may be embodied in many different forms and should not be construed as being limited to the example embodiments set forth herein. Rather, these example embodiments of the disclosure are provided so that this disclosure will be thorough and complete and will convey inventive concepts of the disclosure to those skilled in the art. Also, in the drawings, the thicknesses or sizes of layers are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer, and/or section from another. Thus, a first member, component, region, layer or portion described below may refer to a second member, component, region, layer or portion without departing from the teachings of the present invention.

The present disclosure is intended to solve the above problems including the above problems aims to provide the transparent display apparatus and manufacturing method thereof configured to prevent sharp bending of the wiring by using the wave pattern part in a wave shape, thereby increasing transparency (aesthetics) due to the characteristic of vision which is insensitive to obtuse objects.

Further, the present disclosure is intended to provide the transparent display apparatus and manufacturing method thereof, wherein by forming the overall wiring arrangement in a twisted shape or chain shape, generation of noise or electromagnetic waves such as reflected waveforms can be prevented, thereby facilitating the transmission of surrounding data or control signals and generation of electromagnetic waves harmful to the human body can also be prevented.

Further, the present disclosure is intended to provide the transparent display apparatus and manufacturing method thereof, wherein by forming the overall wiring arrangement in a twisted shape or chain shape, line width can be thickened while maintaining transparency which allows operation with a relatively large current value.

Further, the present disclosure is intended to provide the transparent display apparatus and manufacturing method thereof, wherein pattern breakage in the direction of travel can also be prevented, enabling stable transmission of power or signals. However, these problems are exemplary and do not limit the scope of the present disclosure.

According to an embodiment of the present disclosure formed as described above, it is possible to prevent sharp bending of the wiring by using the wave pattern part in a wave shape, thereby increasing transparency (aesthetics) due to the characteristic of vision which is insensitive to obtuse objects.

By forming the overall wiring arrangement in a twisted shape or chain shape, generation of noise or electromagnetic waves such as reflected waveforms can be prevented, thereby facilitating the transmission of surrounding data or control signals and generation of electromagnetic waves harmful to the human body can also be prevented.

Furthermore, by forming the overall wiring arrangement in a twisted shape or chain shape, line width can be thickened while maintaining transparency which allows operation with a relatively large current value.

Additionally, pattern breakage in the direction of travel can also be prevented, enabling stable transmission of power or signals. However, the scope of the present disclosure is not limited by these effects.

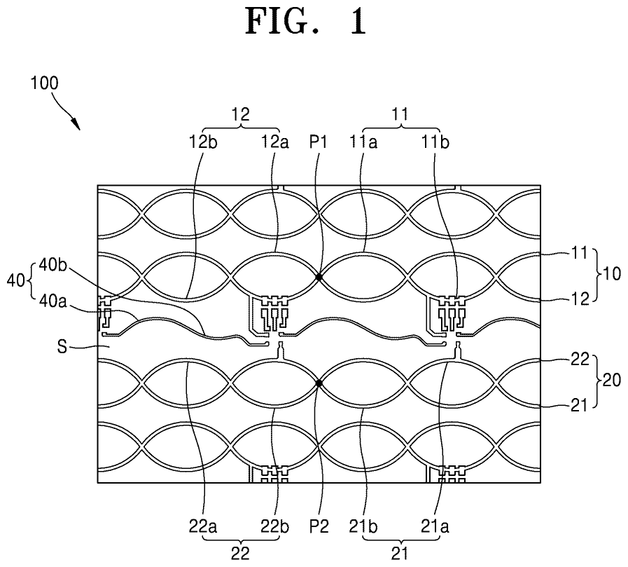

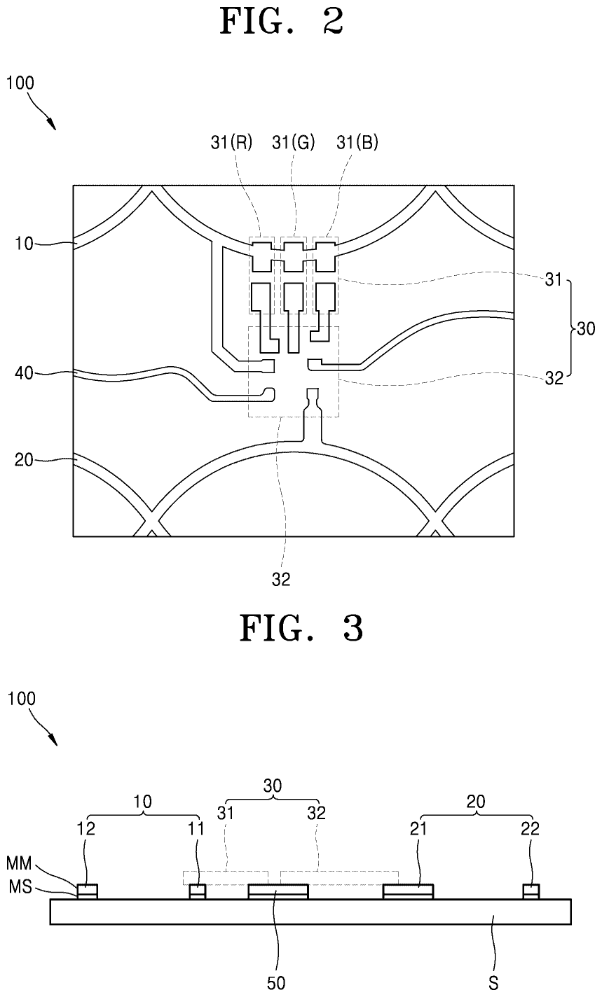

FIG. 1 is a top plan view showing a transparent display apparatus according to some embodiments of the present disclosure, and FIG. 2 is an enlarged top plan view showing the transparent display apparatus of FIG. 1.

As illustrated in FIGS. 1 to 3, the transparent display apparatus 100 according to some embodiments of the present disclosure may include a light transmitting substrate S, a first power wire 10, a second power wire 20, and a light emitting part 30.

As for the light transmitting substrate S, not only glass or acryl, but any transparent or translucent materials such as polydimethylsiloxane (PDMS), polymethyl methacrylate (PMMA), poly(N,N-dimethylacrylamide) (PDMA), polypropylene (PP), and polyimide (PI), polyamide imide, polycarbonate (PC), polyarylate, poly(3,4-ethylenedioxythiophene) (PEDOT), polyetherimide, polyethylene naphthalate, polyphthalamide, polyethylene terephthalate (PET) and the like may by applied.

For the light transmitting substrate S, both panel-type hard materials as well as film-type flexible and soft materials may be applied.

The first power wire 10 may be formed on a part of the light transmitting substrate S extending in the length direction and may be a wiring layer that supplies positive or negative power to the light emitting part 30.

The first power wire 10 may be formed in a double cross-wiring arrangement including a first wave pattern part 11 in a sine wave shape and a second wave pattern part 12 in an arcsine wave shape.

The first wave pattern part 11 may be formed by repeatedly connecting a curve-shaped first peak part 11a and a curve-shaped first valley part 11b in an overall forward wave shape in the length direction to prevent sharp bending.

Similarly, the second wave pattern part 12 may be formed in a reverse wave shape in the length direction by repeatedly connecting a curve-shaped second peak part 12a and a curve-shaped second valley part 12b in the length direction to prevent sharp bending.

Thus, the first wave pattern part 11 and the second wave pattern part 12 may be formed in a double cross wiring arrangement in an overall twisted shape or chain shape by crossing with respect to the first intersection P1 to supply power even if either one of the first wave pattern part 11 or the second wave pattern part 12 is disconnected, wherein the first peak part 11a and the second valley part 12b correspond to each other, and the first valley part 11b and the second peak part 12a correspond to each other.

The second power wire 20 is formed on the other part of the light transmitting substrate S extending in the length direction parallel to the first power wire 10 and may be a wiring layer that supplies negative or positive power to the light emitting part 30.

The second power wire 20 may be formed in a double cross-wire configuration including a third wave pattern part 21 in a sine wave shape and a fourth wave pattern part 22 in an arcsine wave shape.

The third wave pattern part 21 may be formed by repeatedly connecting a curve-shaped third peak part 21a and a curve-shaped third valley part 21b in an overall forward wave shape in the length direction to prevent sharp bending.

The fourth wave pattern part 22 may also be formed by repeatedly connecting a curve-shaped fourth peak part 22a and a curve-shaped fourth valley part 22b in an overall reverse wave shape in the length direction to prevent sharp bending.

Thus, the third wave pattern part 21 and the fourth wave pattern part 22 may be formed in a double cross wiring arrangement in an overall twisted shape or chain shape by crossing with respect to the second intersection P2 to supply power even if either one of the third wave pattern part 21 or the fourth wave pattern part 22 is disconnected, wherein the third peak part 21a and the fourth valley part 22b correspond to each other, and the third valley part 21b and the fourth peak part 22a correspond to each other.

The light emitting part 30 is a part which receives power through the first power wire 10 and the second power wire 20 and emits light, and may include a light emitting device 31 and a driving device 32.

The light emitting device 31 may be at least one LED formed between the first power wire 10 and the second power wire 20, including a first pad electrically connected to the first power wire 10 and a second pad electrically connected to the second power wire 20 to receive DC power from the first power wire 10 and the second power wire 20 to emit light.

The light emitting device 31 may be formed between the first power wire 10 and the second power wire 20 so that the red light emitting device R, green light emitting device G, and blue light emitting device B, a total of three can form one pixel.

The light emitting device 31 may be a flip chip form LED (Light Emitting Diode) in which the first pad and the second pad are formed on the lower surface.

The light emitting device 31 is not necessarily limited to the flip chip form and may also be applied to LEDs including inorganic light emitting chips of various colors in a non-flip form with the pads formed on the upper surface. The light emitting device 31 may be applied to all types of LEDs, such as mini LEDs and micro LEDs, as well as general LEDs.

That is, although not shown, it is possible to apply a light emitting device having a bonding wire applied to the terminal, or a light emitting device having a bonding wire applied partially to the first or the second terminal.

Additionally, a horizontal or vertical light emitting devices or the like can be applied.

However, for miniaturization and ultra-thinness of the product, a flip chip form may be desirable.

The light emitting device 31 may be formed by epitaxially growing a nitride semiconductor, such as InN, AlN, InGaN, AlGaN, InGaAlN, or InGaAlN, on a sapphire growth substrate or a silicon carbide substrate by a vapor phase growth method, such as, for example, a MOCVD method. Further, the light emitting device 31 may be formed using semiconductors such as ZnO, ZnS, ZnSe, SiC, GaP, GaAlAs, and AlInGaP in addition to nitride semiconductors. The semiconductors can use a laminate formed in the order of an n-type semiconductor layer, a light emitting layer, and a p-type semiconductor layer. The light emitting layer (active layer) may use a laminated semiconductor having a multi-quantum well structure, a single quantum well structure, or a double hetero-structure. Further, the light emitting device 31 may be selected with any wavelength depending on the application, such as display or lighting applications.

Here, an insulative substrate, a conductive substrate, or a semiconductor substrate may be used as a growth substrate according to necessity. For example, the growth substrate may be sapphire, SiC, Si, MgAl₂O₄, MgO, LiAlO₂, LiGaO₂, GaN. For epigrowth of GaN materials, the GaN substrate which is a substrate of a same type may be applied.

The driving device 32 may be a driving component, such as a driver IC which is electrically connected to the light emitting device 31 to drive the light emitting device 31.

The driving device 32 includes a drive circuit internally and may be formed in various forms to supply power to the light emitting device 31, control the drive voltage, process feedback signals, control the driving brightness of the light emitting device 31, or calibrate the light amount of the light emitting device 31 according to the reference light amount of other light emitting devices.

The transparent display apparatus 100 according to some embodiments of the present disclosure may further include a signal control wire 40 formed between the first power wire 10 and the second power wire 20, and electrically connected to the driving device 32.

The signal control wire 40 may be formed by repeatedly connecting a curve-shaped peak part 40a and a curve-shaped valley part 40b in an overall wave shape in the length direction to prevent sharp bending.

The transparent display apparatus 100 according to some embodiments of the present disclosure may further include a connection wire 50 formed between the first power wire 10 and the second power wire 20 to facilitate electrical connection between the light emitting device 31 and the driving device 32.

The first power wire 10, the second power wire 20, the signal control wire 40, and the connection wire 50 may be formed simultaneously by a circuit printing process.

As shown in FIGS. 1 and 3, the first power wire 10 and the second power wire 20 may be arranged in a line so that the first intersections P1 of the first power wire 10 and the second intersections P2 of the second power wire 20 correspond to each other.

Therefore, by using the wave pattern parts 11, 12, 21, and 22 formed in wave shapes, it is possible to prevent sharp bending of the wiring, thereby increasing transparency (aesthetics) due to the characteristic of vision which is insensitive to obtuse objects.

By forming the overall wiring arrangement in a twisted shape or chain shape, generation of noise or electromagnetic waves such as reflected waveforms can be prevented, thereby facilitating the transmission of surrounding data or control signals and generation of electromagnetic waves harmful to the human body can also be prevented.

Furthermore, by forming the overall wiring arrangement in a twisted shape or chain shape, line width can be thickened while maintaining transparency which allows operation with a relatively large current value.

Additionally, pattern breakage in the direction of travel can also be prevented, enabling stable transmission of power or signals.

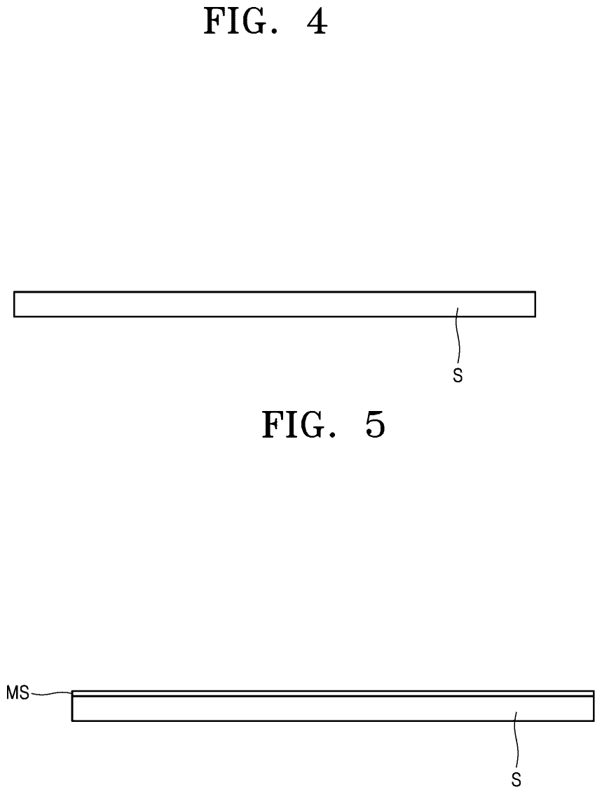

FIGS. 4 to 10 are cross-sectional side views showing examples of manufacturing processes of the transparent display apparatus of FIG. 1 step by step.

As illustrated in FIGS. 4 to 10, examples of manufacturing processes for the transparent display apparatus 100 according to some embodiments of the present disclosure is described as follows: First, as shown in FIG. 4, a light transmitting substrate is prepared, and as shown in FIG. 5, a metal seed layer MS can be collectively formed on an entire upper surface by sputtering to form the first power wire 10 on the light transmitting substrate S.

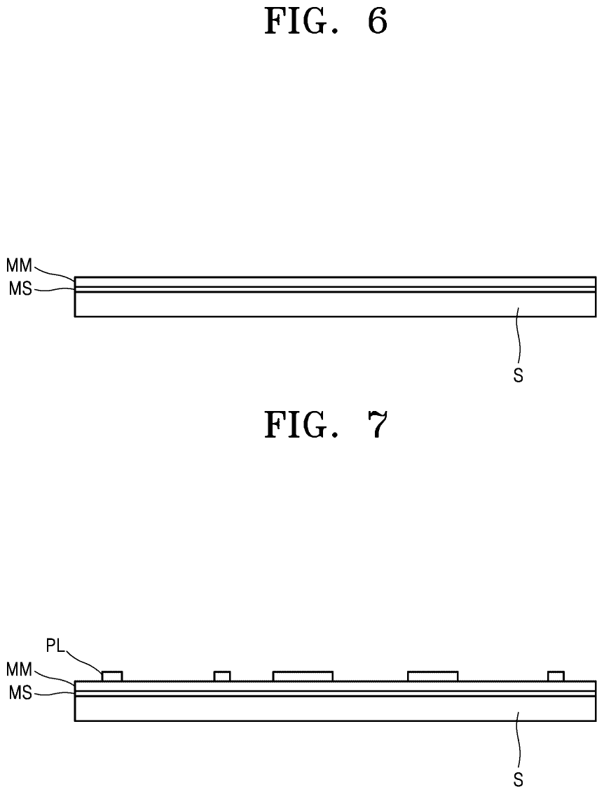

Subsequently, as shown in FIG. 6, the main metal layer MM may be formed thick collectively by plating on the metal seed layer MS.

Subsequently, as shown in FIG. 7, a pattern can be partially formed on the main metal layer MM in the shape of the first wave pattern part 11 by going through processes such as exposure or development of a printed-circuit layer PL such as a photoresist.

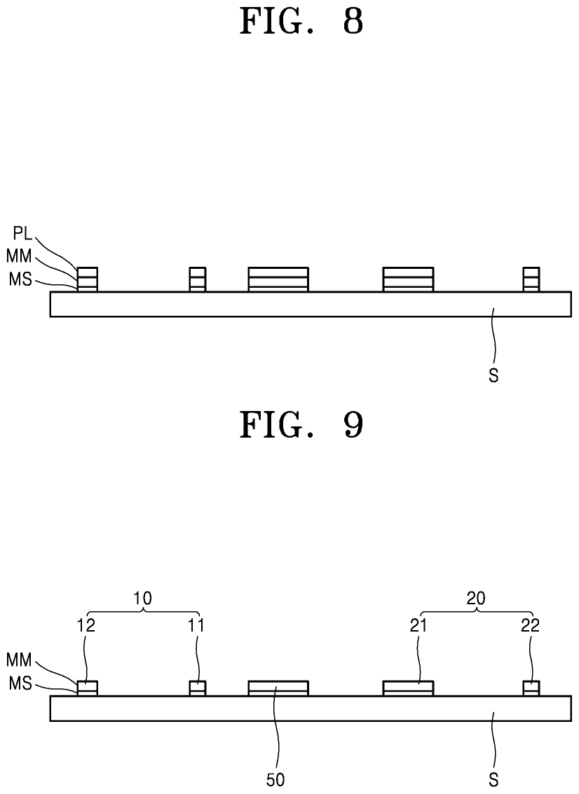

Subsequently, as shown in FIG. 8, the main metal layer MM except for the main metal layer MM covered with the printed-circuit layer PL is etched to form the first power wire 10, and as shown in FIG. 9, the remaining printed-circuit layer PL can be removed.

Here, the first wave pattern part 11 may be formed by repeatedly connecting a curve-shaped first peak part 11a and a curve-shaped first valley part 11b in an overall wave shape in the length direction to prevent sharp bending of the first power wire 10.

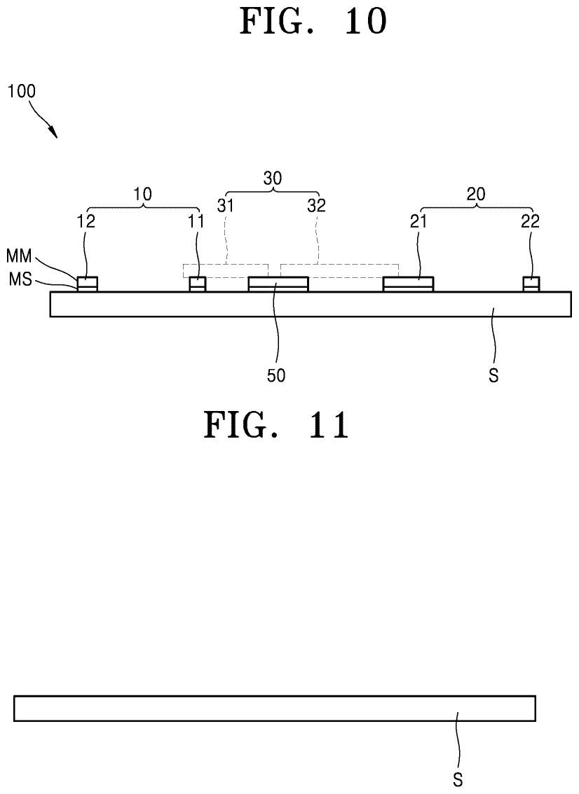

Subsequently, as shown in FIG. 10, the light emitting part 30 which receives power through the first power wire 10 and emits light, which are the light emitting device 31 and the driving device 32, can be mounted on the first power wire 10.

FIGS. 11 to 16 are cross-sectional side views showing other examples of the manufacturing processes of the transparent display apparatus 100 of FIG. 1 step by step.

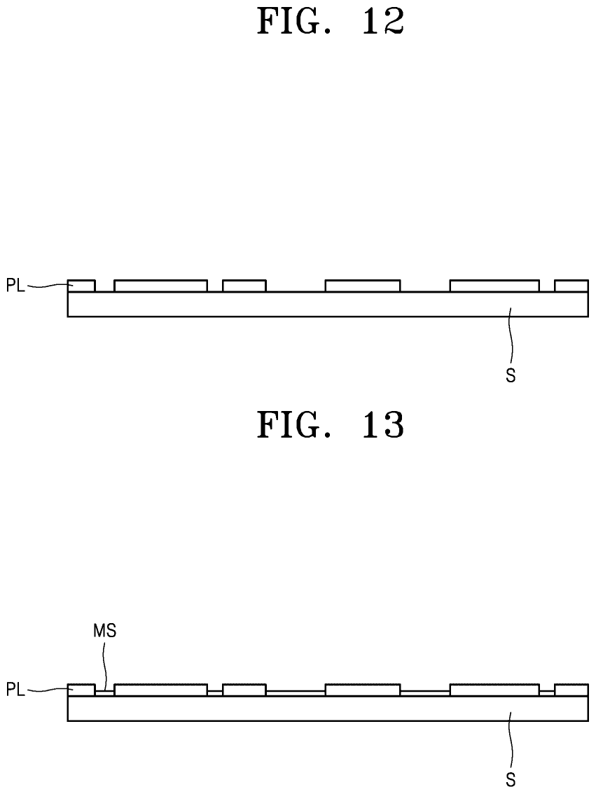

As shown in FIGS. 11 to 16, other examples of the manufacturing processes of the transparent display apparatus 100 according to some embodiments of the present disclosure is described as follows: First, as shown in FIG. 11, a light transmitting substrate S is prepared, and as shown in FIG. 12, the printed-circuit layer PL such as a photoresist can be formed in the shape of the first wave pattern part 11 on the light transmitting substrate S by partially patterning through exposure or development, so that the first power wire 10 can be formed on the light transmitting substrate S.

Subsequently, as shown in FIG. 13, the metal seed layer MS can be partially formed on a pattern formed at the printed-circuit layer PL by sputtering.

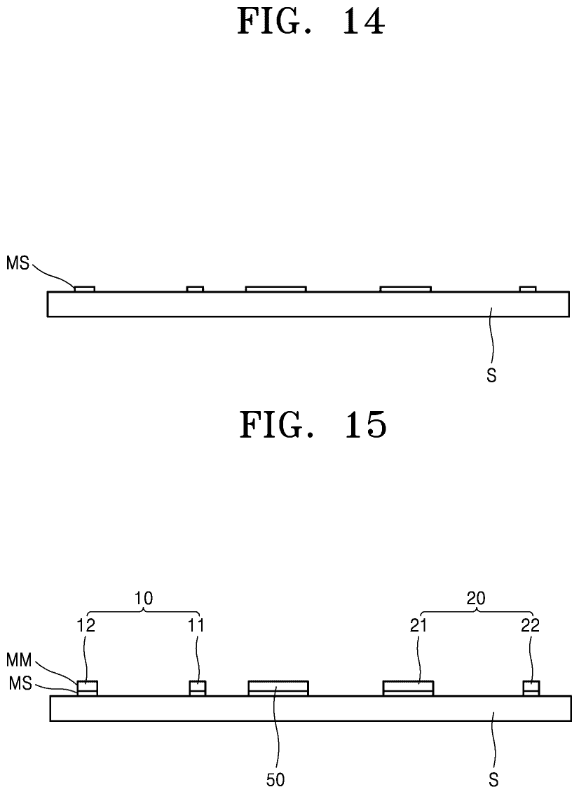

Subsequently, as shown in FIG. 14, the printed-circuit layer PL is removed, and as shown in FIG. 15, the main metal layer MM can be formed by plating on the remaining metal seed layer MS to form the first power wire 10.

Here, the first wave pattern part 11 may be formed by repeatedly connecting a curve-shaped first peak part 11a and a curve-shaped first valley part 11b in an overall wave shape in the length direction to prevent sharp bending of the first power wire 10.

Subsequently, as shown in FIG. 16, the light emitting part 30 which receives power through the first power wire 10 and emits light, which are the light emitting device 31 and the driving device 32, can be mounted on the first power wire 10.

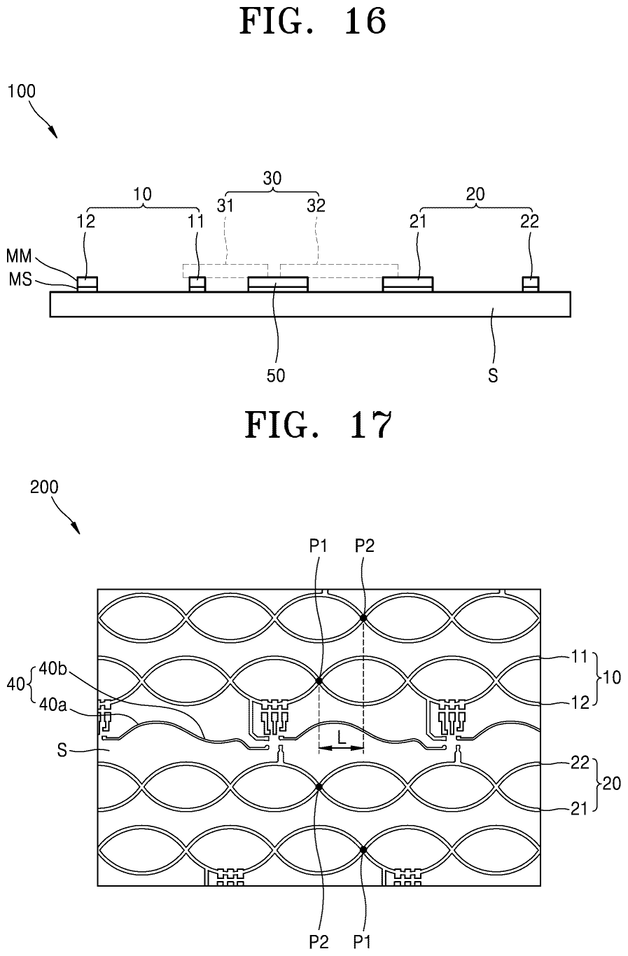

FIG. 17 is a top plan view showing a transparent display apparatus 200 according to some other embodiments of the present disclosure.

As shown in FIG. 17, the first power wire 10 and the second power wire 20 of the transparent display apparatus 200 according to some other embodiments of the present disclosure, the first intersection P1 of the first power wire 10 and second intersection P2 of the second power wire 20 may be arranged in a zigzag manner dislocated from each other by the spacing distance L.

Valleys are disposed between peaks to expand space utilization, and visibility (transparency) can be improved with the zigzag optical illusion effect.

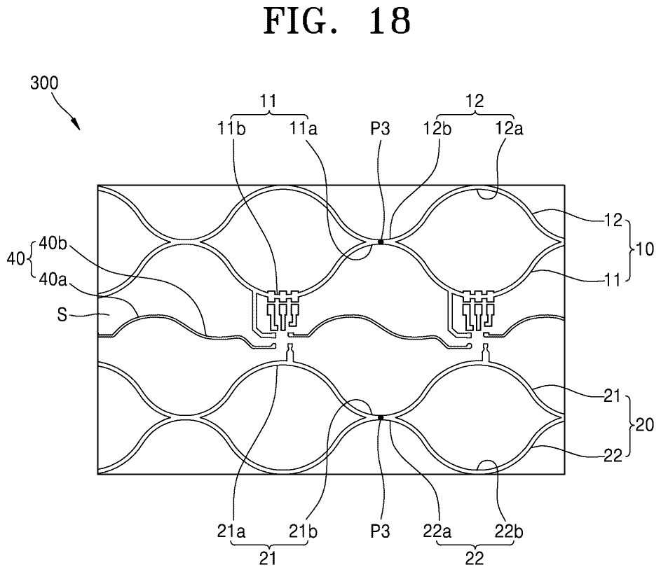

FIG. 18 is a top plan view showing a transparent display apparatus 300 according to some further embodiments of the present disclosure.

As shown in FIG. 18, a first wave pattern part 11 and a second wave pattern part 12 of a transparent display apparatus 300 according to some further embodiments of the present disclosure may be formed in an overall streamlined shape, wherein a first valley part 11b and a second peak part 12a are connected to each other at a connection point P3 to supply power even if either one of the first wave pattern part 11 or the second wave pattern part 12 is disconnected.

By reducing intersections P1, P2 and using the connection point P3 instead, space utility can be expanded, and visibility (transparency) can be improved due to an optical illusion effect using a streamlined shape.

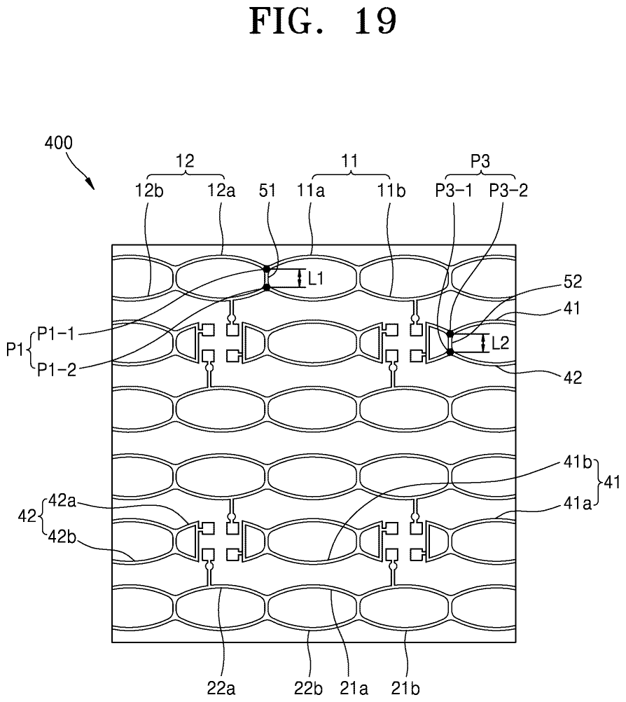

FIG. 19 is a top plan view showing a transparent display apparatus 400 according to some further embodiments of the present disclosure.

As shown in FIG. 19, in a first intersection P1 of a transparent display apparatus 400 according to some other embodiments of the present disclosure, a first extension wire 51 may be formed extending as much as a first extension length L1 in a vertical direction of a length direction from (1-1)th intersection P1-1 to (1-2)th intersection P1-2.

By using the first extension wire 51 not only in the length direction but also in the vertical direction of the length direction overall, wiring stability and durability can be greatly improved against external forces in all directions of the length direction and the vertical direction of the length direction.

Further, a signal control wire 40 can include a fifth wave pattern part 41 formed by repeatedly connecting a curve-shaped fifth peak part 41a and a curve-shaped fifth valley part 41b in an overall wave shape in the length direction to prevent sharp bending, and a sixth wave pattern part 42 formed by repeatedly connecting a curve-shaped sixth peak part 42a and a curve-shaped sixth valley part 42b in an overall wave shape in the length direction to prevent sharp bending, which intersects the fifth wave pattern part 41 with respect to a third intersection P3.

Here, in the third intersection P3, a second extension wire 52 may be formed extending as much as a second extension length L2 from (3-1)th intersection P3-1 to (3-2)th intersection P3-2.

By duplicating the signal control wire 40 into the fifth wave pattern part 41 and the sixth wave pattern part 42, signals can be transmitted even if either one of the fifth wave pattern part 41 or the sixth wave pattern part 42 is disconnected. Further, by using the second extension wire 52 not only in the length direction but also in the vertical direction of the length direction overall, wiring stability and durability can be greatly improved against external forces in all directions of the length direction and the vertical direction of the length direction.

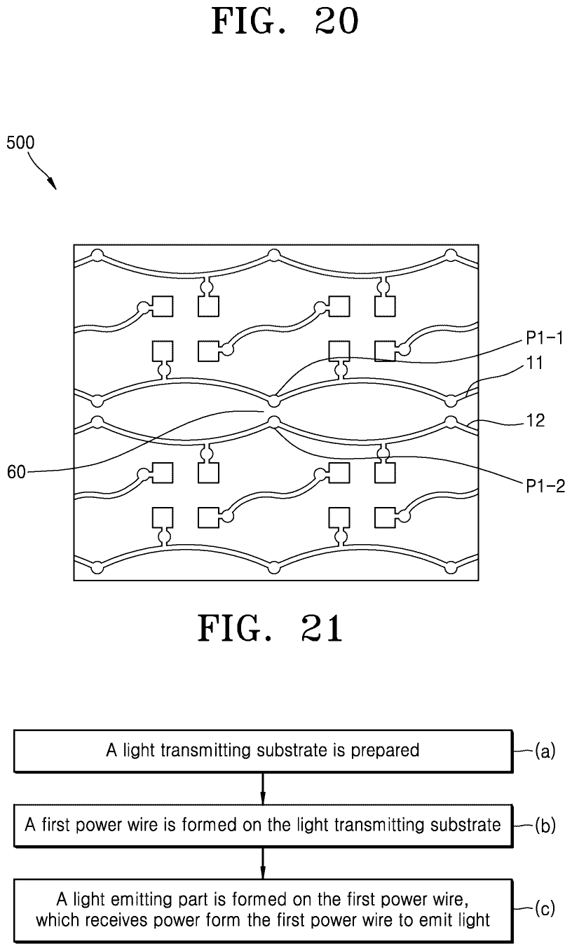

FIG. 20 is a top plan view showing a transparent display apparatus 500 according to some further embodiments of the present disclosure.

As shown in FIG. 20, the transparent display apparatus 500 according to some further embodiments of the present disclosure may be formed in an overall vertically corresponding wave shape, wherein at least a portion of a first extension wire 51 may be shorted at a short part 60.

Therefore, according to necessity, the length of the first extension wire 51 may not be maintained fixedly against an external force in the vertical direction of the length direction but may be flexibly responded to some extent by the short part 60.

FIG. 21 is a flowchart showing a manufacturing method of a transparent display apparatus according to some embodiments of the present disclosure.

As shown in FIGS. 1 to 21, the manufacturing method of the transparent display apparatus according to some embodiments of the present disclosure includes a step (a) wherein a light transmitting substrate S is prepared, a step (b) wherein the first power wire 10 is formed on the light transmitting substrate S, and a step (c) wherein the light emitting part 30 is formed on the first power wire 10, which receives power from the first power wire 10 to emit light, wherein in the step (b), the first wave pattern part 11 is formed by repeatedly connecting the curve-shaped first peak part 11a and the curve-shaped first valley part 11b in an overall wave shape in the length direction to prevent sharp bending.

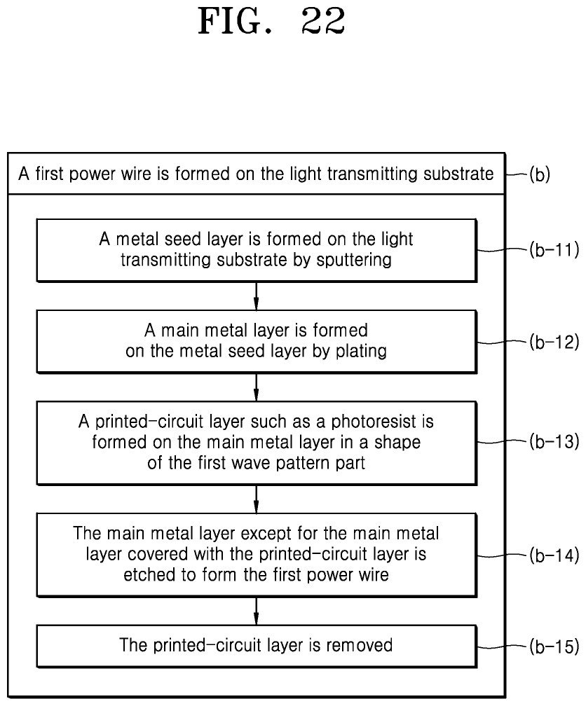

FIG. 22 is a flowchart showing an example of step (b) of the manufacturing method of the transparent display apparatus of FIG. 21.

As shown in FIGS. 1 to 22, the step (b) may include a step (b-11) wherein the metal seed layer MS is formed on the light transmitting substrate S by sputtering, a step (b-12) wherein the main metal layer MM is formed on the metal seed layer MS by plating, a step (b-13) wherein the printed-circuit layer PL such as a photoresist is formed on the main metal layer MM in a shape of the first wave pattern part 11, a step (b-14) wherein the main metal layer MM except for the main metal layer MM covered with the printed-circuit layer PL is etched to form the first power wire 10, and a step (b-15) wherein the printed-circuit layer PL is removed.

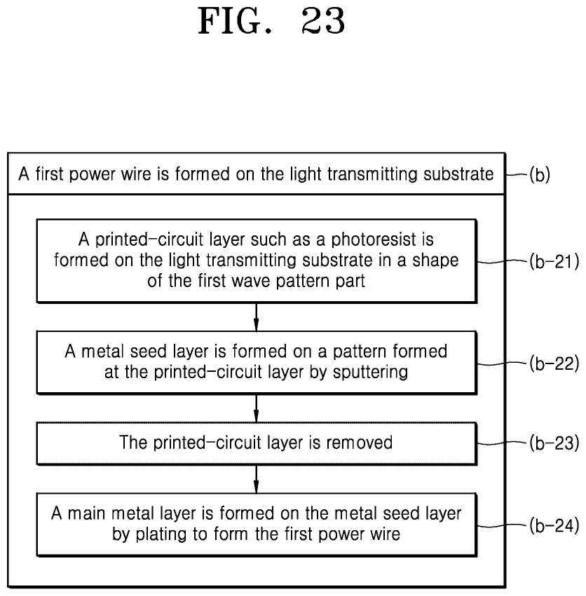

FIG. 23 is a flowchart showing another example of step (b) of the manufacturing method of the transparent display apparatus of FIG. 21.

As shown in FIGS. 1 to 23, the step (b) may include a step (b-21) wherein the printed-circuit layer PL such as a photoresist is formed on the light transmitting substrate S in the shape of the first wave pattern part 11, a step (b-22) wherein the metal seed layer MS is formed on a pattern formed at the printed-circuit layer PL by sputtering, a step (b-23) wherein the printed-circuit layer PL is removed, and a step (b-24) wherein the main metal layer MM is formed on the metal seed layer MS by plating to form the first power wire 10.

The present disclosure has been described with reference to the embodiments illustrated in the drawings, but these embodiments are merely illustrative and it should be understood by a person with ordinary skill in the art that various modifications and equivalent embodiments can be made without departing from the scope of the present disclosure. Therefore, the true technical protective scope of the present disclosure must be determined based on the technical concept of the appended claims.

### REFERENCE SIGNS LIST

S: Light transmitting substrate
10: First power wire
11: First wave pattern part
11a: First peak part
11b: First valley part
12: Second wave pattern part
12a: Second peak part
12b: Second valley part
P1: First intersection
20: Second power wire
21: Third wave pattern part
21a: Third peak part
21b: Third valley part
22: Fourth wave pattern part
22a: Fourth peak part
22b: Fourth valley part
P2: Second intersection
30: Light emitting part
31: Light emitting device
32: Driving device
40: Signal control wire
40: Peak part
40b: Valley part
50: Connection wire
P3: Connection point
MS: Metal seed layer
MM: Main metal layer
PL: Printed-circuit layer
L: Spacing distance
51: Extension wire
P1-1: (1-1)th intersection
P1-2: (1-2)th intersection
L1: First extension length
41: Fifth wave pattern part
41a: Peak part
41b: Valley part
42: Sixth wave pattern part
42a: Peak part
42b: Valley part
52: Second extension wire
P3: Third intersection
P3-1: (3-1)th intersection
P3-2: (3-2)th intersection
L2: Second extension length
60: Short part
100, 200, 300, 400, 500: Transparent display apparatus

What is claimed is:

1. A transparent display apparatus comprising:
a light transmitting substrate;
a first power wire formed on the light transmitting substrate, which supplies power; and
a light emitting part which receives power from the first power wire to emit light;
wherein the first power wire comprises a first wave pattern part formed by repeatedly connecting a curve-shaped first peak part and a curve-shaped first valley part in an overall wave shape in a length direction to prevent sharp bending.

2. The transparent display apparatus of claim 1,
wherein the first power wire further comprises
a second wave pattern part formed by repeatedly connecting a curve-shaped second peak part and a curve-shaped second valley part in an overall wave shape in the length direction to prevent sharp bending.

3. The transparent display apparatus of claim 2,
wherein the first wave pattern part and the second wave pattern part are formed in an overall twisted shape or chain shape by crossing with respect to a first intersection to supply power even if either one of the first wave pattern part or the second wave pattern part is disconnected, wherein the first peak part and the second valley part correspond to each other, and the first valley part and the second peak part correspond to each other.

4. The transparent display apparatus of claim 3, further comprising:
a second power wire formed on the light transmitting substrate, which supplies power,
wherein the second power wire comprises a third wave pattern part formed by repeatedly connecting a curve-shaped third peak part and a curve-shaped third valley part in an overall wave shape in the length direction to prevent sharp bending; and
a fourth wave pattern part formed by repeatedly connecting a curve-shaped fourth peak part and a curve-shaped fourth valley part in an overall wave shape in the length direction to prevent sharp bending.

5. The transparent display apparatus of claim 4,
wherein the third wave pattern part and the fourth wave pattern part are formed in an overall twisted shape or chain shape by crossing with respect to a second intersection to supply power even if either one of the third wave pattern part or the fourth wave pattern part is disconnected, wherein the third peak part and the fourth valley part correspond to each other and the third valley part, and the fourth peak part correspond to each other.

6. The transparent display apparatus of claim 5,
wherein the light emitting part comprises
at least one light emitting device formed between the first power wire and the second power wire comprising a first pad electrically connected to the first power wire and a second pad electrically connected to the second power wire; and
a driving device electrically connected to the light emitting device to drive the light emitting device.

7. The transparent display apparatus of claim 6, further comprising
a signal control wire formed between the first power wire and the second power wire and electrically connected to the driving device.

8. The transparent display apparatus of claim 7,
wherein the signal control wire is formed by repeatedly connecting a curve-shaped peak part and a curve-shaped valley part in an overall wave shape in the length direction to prevent sharp bending.

9. The transparent display apparatus of claim 5,
wherein the first power wire and the second power wire are arranged in a line so that the first intersections of the first power wire and the second intersections of the second power wire correspond to each other.

10. The transparent display apparatus of claim 5,
wherein the first power wire and the second power wire are arranged in a zigzag manner so that the first intersections of the first power wire and the second intersections of the second power wire are dislocated from each other.

11. The transparent display apparatus of claim 2,
wherein the first wave pattern part and the second wave pattern part are formed in an overall streamlined shape, wherein the first valley part and the second peak part are connected to each other at a connection point to supply power even if either one of the first wave pattern part and the second wave pattern part is disconnected.

12. The transparent display apparatus of claim 3,
wherein in the first intersection,
a first extension wire is formed extending as much as a first extension length from a (1-1)th intersection to a (1-2)th intersection.

13. The transparent display apparatus of claim 8,
wherein the signal control wire comprises
a fifth wave pattern part formed by repeatedly connecting a curve-shaped fifth peak part and a curve-shaped fifth valley part in an overall wave shape in the length direction to prevent sharp bending; and
a sixth wave pattern part formed by repeatedly connecting a curve-shaped sixth peak part and a curve-shaped sixth valley part in an overall wave shape in the length direction to prevent sharp bending, which intersects the fifth wave pattern part with respect to a third intersection;
wherein in the third intersection,
a second extension wire is formed extending as much as a second extension length from a (3-1)th intersection to a (3-2)th intersection.

14. The transparent display apparatus of claim 12,
wherein at least some of the first extension wires are shorted.

15. A manufacturing method of a transparent display apparatus comprising:
a step (a) wherein a light transmitting substrate is prepared;
a step (b) wherein a first power wire is formed on the light transmitting substrate; and
a step (c) wherein a light emitting part is formed on the first power wire, which receives power form the first power wire to emit light;
wherein in the step (b),
a first wave pattern part is formed by repeatedly connecting a curve-shaped first peak part and a curve-shaped first valley part in an overall wave shape in the length direction to prevent sharp bending.

16. The manufacturing method of claim 15,
wherein the step (b) comprises
a step (b-11) wherein a metal seed layer is formed on the light transmitting substrate by sputtering;
a step (b-12) wherein a main metal layer is formed on the metal seed layer by plating;
a step (b-13) wherein a printed-circuit layer such as a photoresist is formed on the main metal layer in a shape of the first wave pattern part;
a step (b-14) wherein the main metal layer except for the main metal layer covered with the printed-circuit layer is etched to form the first power wire; and
a step (b-15) wherein the printed-circuit layer is removed.

17. The manufacturing method of claim 15,
wherein the step (b) comprises
a step (b-21) wherein a printed-circuit layer such as a photoresist is formed on the light transmitting substrate in a shape of the first wave pattern part;
a step (b-22) wherein a metal seed layer is formed on a pattern formed at printed-circuit layer by sputtering;
a step (b-23) wherein the printed-circuit layer is removed; and
a step (b-24) wherein a main metal layer is formed on the metal seed layer by plating to form the first power wire.
